(19) United States
(12) Patent Application Publication
(10) Pub. No.: US 2025/0335689 A1
(43) Pub. Date: Oct. 30, 2025

(54) CFET DEVICE OPTIMIZATION BY MULTIPLE CELL HEIGHT PLACEMENT

(71) Applicant: Taiwan Semiconductor Manufacturing Co., Ltd., Hsinchu (TW)

(72) Inventors: Chun-Yen Lin, Hsinchu (TW); Wei-Cheng Tzeng, Taipei (TW); Jun-Yu Lin, Chiayi County (TW); Wei-Cheng Lin, Taichung City (TW); Jiann-Tyng Tzeng, Hsinchu (TW)

(21) Appl. No.: 19/260,009

(22) Filed: Jul. 3, 2025

Related U.S. Application Data
(63) Continuation of application No. 18/785,664, filed on Jul. 26, 2024.
(60) Provisional application No. 63/638,507, filed on Apr. 25, 2024.

(51) Int. Cl. G06F 30/392

(52) U.S. Cl. CPC G06F 30/392

(57) ABSTRACT

A structure includes a standard cell, which includes a first single-height part and a second single-height part. The first single-height part comprises a first VDD line, a first VSS line, and a first input metal line. The second single-height part is abutting the first single-height part to form an interface. The second single-height part comprises a second VDD line, a second VSS line, and an output metal line. In a top view of the structure, the first input metal line and the output metal line have lengthwise directions parallel to the interface.

### PRIORITY CLAIM AND CROSS-REFERENCE

This application is a continuation of U.S. patent application Ser. No. 18/785,664, filed on Jul. 26, 2024, which application claims the benefit of the following provisionally filed U.S. Patent application: Application No. 63/638,507, filed on Apr. 25, 2024, and entitled “CFET DEVICE OPTIMIZATION BY MULTIPLE CELL HEIGHT PLACEMENT,” which applications are hereby incorporated herein by reference.

### BACKGROUND

Standard cells are the basic building blocks for designing integrated circuits. The standard cells are pre-designed, and saved in design libraries. At the time integrated circuits are laid out, the standard cells are placed, and are interconnected to form circuits. The circuits (including the standard cells) are then manufactured in device dies.

With the increasingly downsizing of integrated circuits, new issues arise, and standard cells may be re-designed to address these issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate views of intermediate stages in the formation of a Complementary Field-Effect Transistor (CFET) in accordance with some embodiments.

FIG. 8 illustrates the circuit schematic of an inverter (INVD4) cell including four inverters connected in parallel in accordance with some embodiments.

FIGS. 9A and 9B illustrate the layout of some features at a front side and a backside, respectively, of an INVD4 inverter cell in accordance with some embodiments.

FIGS. 10A and 10B illustrate the layout of some features at a front side and a backside, respectively, of an INVD4 inverter cell in accordance with some embodiments.

FIG. 11 illustrates the circuit schematic of a NAND cell (ND2D4) including four NAND cells connected in parallel in accordance with some embodiments.

FIGS. 12A and 12B illustrate the layout of some features at a front side and a backside, respectively, of an ND2D4 gate in accordance with some embodiments.

FIGS. 13A and 13B illustrate the layout of some features at a front side and a backside, respectively, of an ND2D4 gate in accordance with some embodiments.

FIG. 14 illustrates a perspective view of a portion of an ND2D4 gate in accordance with some embodiments.

FIG. 15 illustrates a schematic top view of a double-height standard cell and four metal lines that can be accommodated therein in accordance with some embodiments.

FIG. 16 illustrates some performance data of some standard cells in accordance with some embodiments.

FIG. 17 illustrates the speed and the cell pitch penalty of some double-height standard cells in accordance with some embodiments.

FIG. 18 illustrates a device die including both of single-height cells and a double-height cell in accordance with some embodiments.

FIG. 19 illustrates a process flow for forming a CFET in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An inverter (INVD4) including four invertors connected in parallel and a NAND cell (ND2D4) including four NAND cells connected in parallel are provided. In accordance with some embodiments of the present disclosure, the inverter INVD4 and the NAND cell ND2D4 are designed and manufactured using Complementary Field-Effect Transistors (CFETs) and occupying double heights. It is thus able to separate the input metal line(s) further away from output metal line, and the parasitic capacitance formed in between is reduced. Furthermore, it is possible to route signals with short signal length without resorting to long metal lines on the backside of the circuit. The resistance and the performance of the standard cells are thus improved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

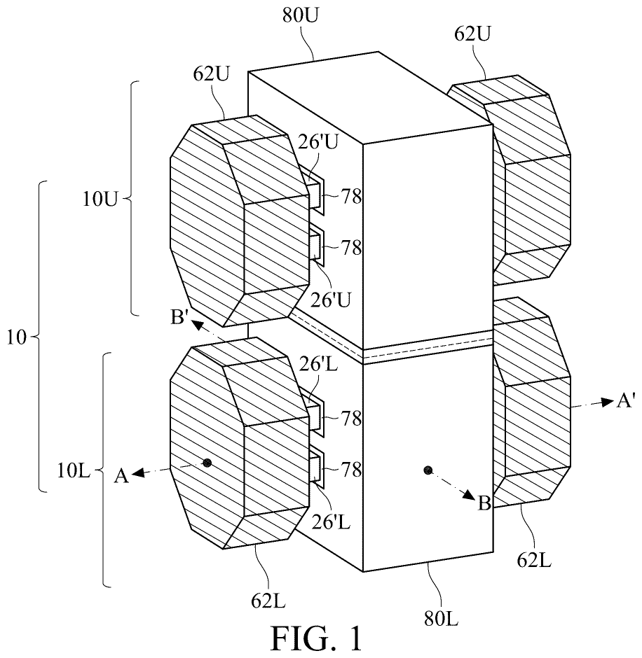

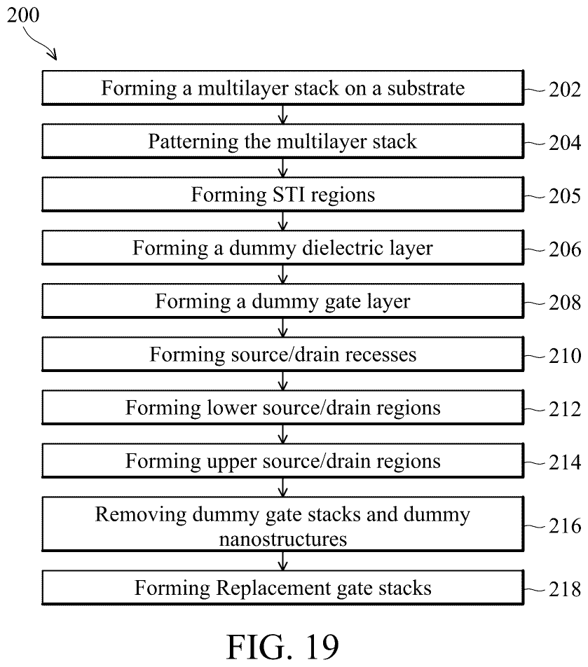

FIGS. 1 through 7 illustrate the views of intermediate stages in the formation of a CFET in accordance with some embodiments of the present disclosure. The corresponding processes are also reflected schematically in the process flow shown in FIG. 19.

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

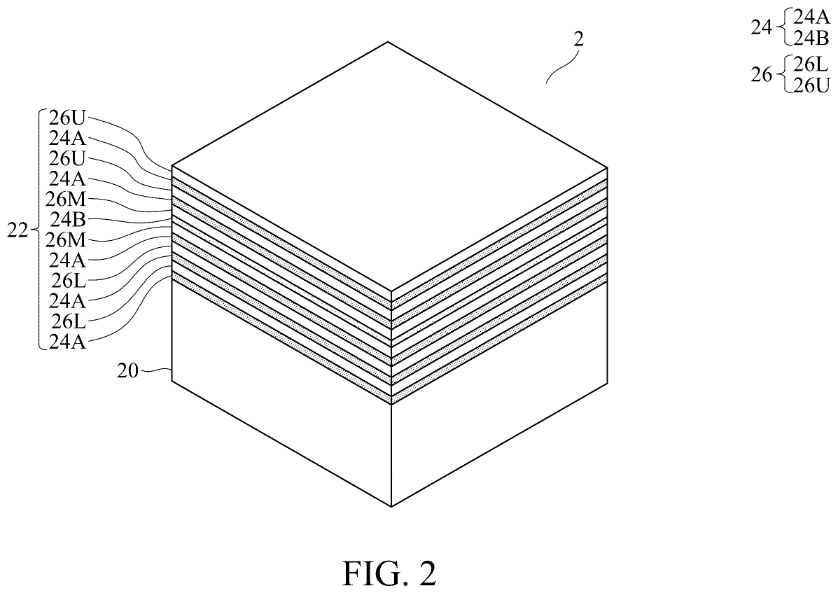

FIGS. 2 through 7 illustrate the cross-sectional views of intermediate stages in the formation of CFETs (as schematically represented in FIG. 1) in accordance with some embodiments. The corresponding processes are also reflected schematically in the process flow 200 as shown in FIG. 16.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The respective process is illustrated as process 202 in the process flow 200 as shown in FIG. 19. The multi-layer stack 22 includes alternating dummy semiconductor layers 24 (including dummy semiconductor layers 24A and a dummy semiconductor layer 24B) and semiconductor layers 26 (including lower semiconductor layers 26L, middle semiconductor layers 26M, and upper semiconductor layers 26U). Lower semiconductor layers 26L and upper semiconductor layers 26U are for forming a lower FET and an upper FET, respectively.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

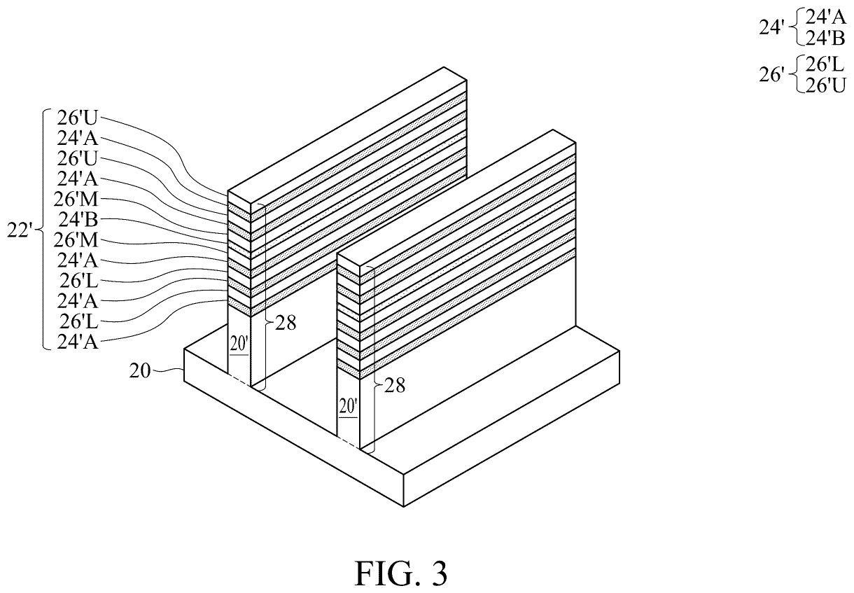

In FIG. 3, multi-layer stack 22 and substrate 20 are patterned to form semiconductor strips 28. The respective process is illustrated as process 204 in the process flow 200 as shown in FIG. 19. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

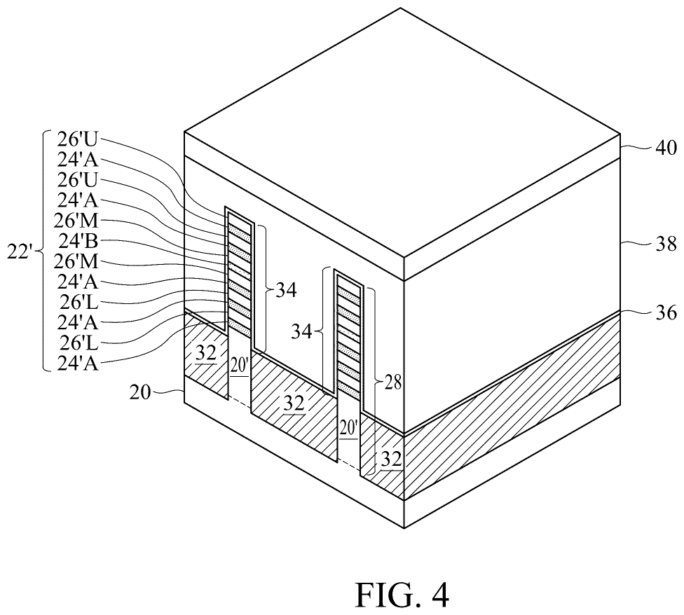

In FIG. 4, isolation regions 32 (Shallow Trench Isolation (STI) regions) are formed over the substrate 20 and between adjacent semiconductor strips 28. The respective process is illustrated as process 205 in the process flow 200 as shown in FIG. 19. Isolation regions 32 may include a dielectric liner and a dielectric material over the dielectric liner. Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 19. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 19. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

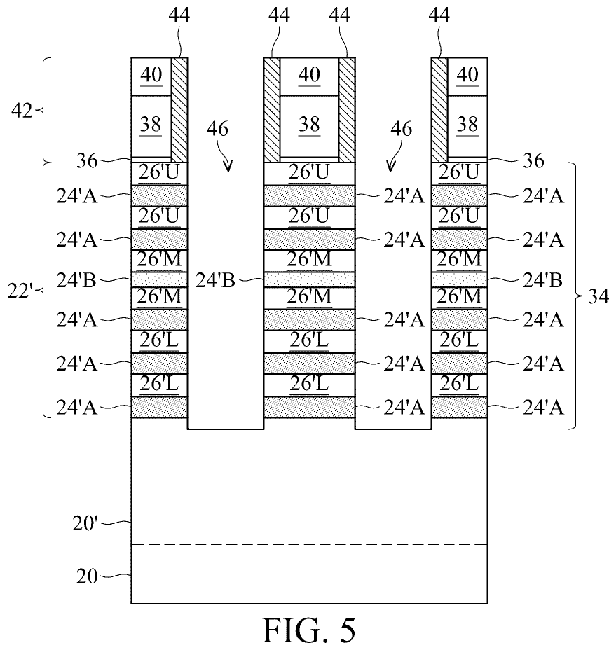

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 (not shown in the figures) are also formed.

Source/drain recesses 46 are then formed in semiconductor strips 28. The respective process is illustrated as process 210 in the process flow 200 as shown in FIG. 19. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28.

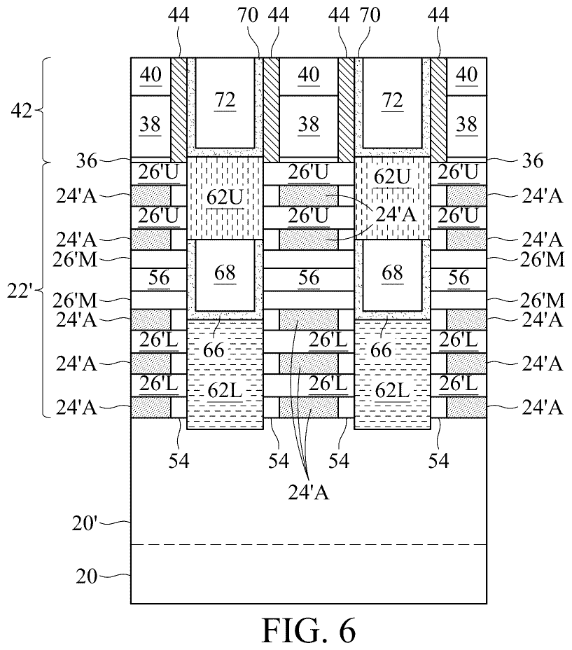

In a subsequent process, dummy nanostructures 24′A are laterally recessed, and a dielectric material is filled into the respective recesses to form inner spacers 54, which are dielectric spacers. The resulting structure is shown in FIG. 6. Also, dummy nanostructures 24′B are also removed, and are filled with a dielectric material to form dielectric isolation layers 56.

Next, lower epitaxial source/drain regions 62L are formed in the lower portions of the source/drain recesses 46 (FIG. 5). The respective process is illustrated as process 212 in the process flow 200 as shown in FIG. 19. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The respective process is illustrated as process 214 in the process flow 200 as shown in FIG. 19. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

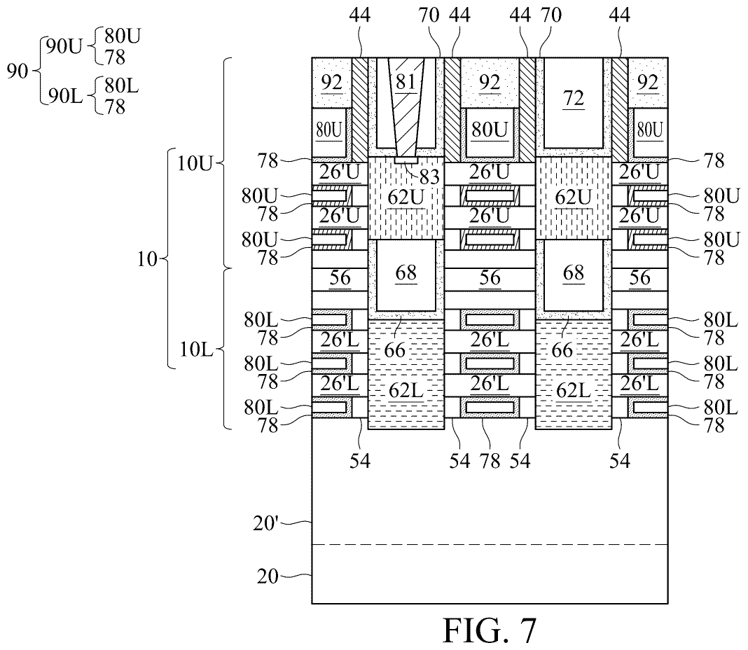

The dummy gate stacks 42 are then removed in one or more etching processes, and replacement gate stacks 90 (including gate stacks 90L and 90U) are formed in the respective recesses, as shown in FIG. 7. The respective processes are illustrated as processes 216 and 218 in the process flow 200 as shown in FIG. 19. Gate stacks 90L include gate spacers 78 and gate electrodes 80L. Gate stacks 90U include gate spacers 78 and gate electrodes 80U. Each of gate dielectrics 78 may include an interfacial layer (such as a silicon oxide layer) and a high-k dielectric layer over the interfacial layer.

Dielectric hard masks 92 are formed over the gate stacks 90U. The gate electrodes 80L and 80U include conductive materials, which may provide suitable work-functions to the resulting lower FETs (lower transistors) 10L and upper FETs (upper transistors) 10U. The gate electrodes 80L and 80U may be common gates formed in a same formation process.

FIG. 7 further illustrates the formation of a source/drain contact plug 81 connecting to upper source/drain regions 62U in accordance with some embodiments. Source/drain silicide layers 83 are also formed. The electrical connection to the lower source/drain regions 62L may be through vertical interconnects.

The CFET 10 may be used for forming standard cells, which include the inverters INVD4 and the NAND cells ND2D4, as will be discussed in detail. In the following discussed examples, it is assumed that the lower transistors are p-type transistors, and the upper transistors are n-type transistors. Accordingly, in the respective standard cells such as INVD4 and the ND2D4, the VSS lines (electrical ground) are formed on the front side of the transistors and the respective wafer/die, and the VDD lines (positive power supply) are formed on the backside of the transistors and the respective wafer/die.

In accordance with alternative embodiments, the lower transistors may be n-type transistors, and the upper transistors may be p-type transistors. corresponding, in the respective standard cells such as INVD4 and the ND2D4, the VDD lines may be formed on the front side of the transistors and the respective wafer/die, and the VSS lines may be formed on the backside of the transistors and the respective wafer/die.

Also, the standard cells INVD4 and the ND2D4 include CMOS transistors, each including a p-type transistor and an n-type transistor, with the gates of the p-type transistor and the n-type transistor being interconnected. The CMOS transistors may have the structures shown in FIGS. 1 and 7, with the p-type transistor and the n-type transistor share a common gate 80 (including gate electrodes 80L and 80U, FIGS. 1 and 7).

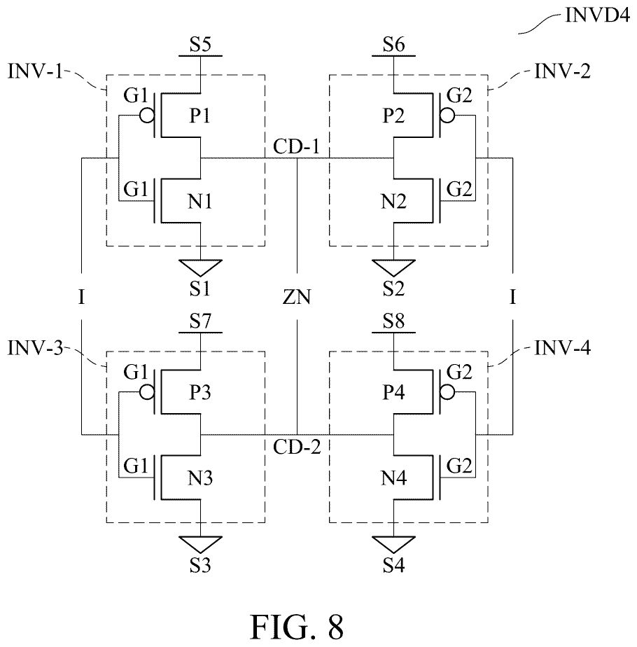

FIG. 8 illustrates the circuit schematic of an inverter INVD4 including four inverters INV-1, INV-2, INV-3, and INV-4 connected in parallel. Inverter INV-1 incudes p-type transistor (alternatively referred to as a PMOS transistor) P1 and n-type transistor (alternatively referred to as an NMOS transistor) N1. Inverter INV-2 includes PMOS transistor P2 and NMOS transistor N2. Inverter INV-3 includes PMOS transistor P3 and NMOS transistor N3. Inverter INV-4 includes PMOS transistor P4 and NMOS transistor N4.

The inverters INV-1, INV-2, INV-3, and INV-4 are connected in parallel to provide higher speed. Input node I is connected to the gates of all PMOS and NMOS transistors. The common drain regions of the four inverters are connected together as the output node ZN.

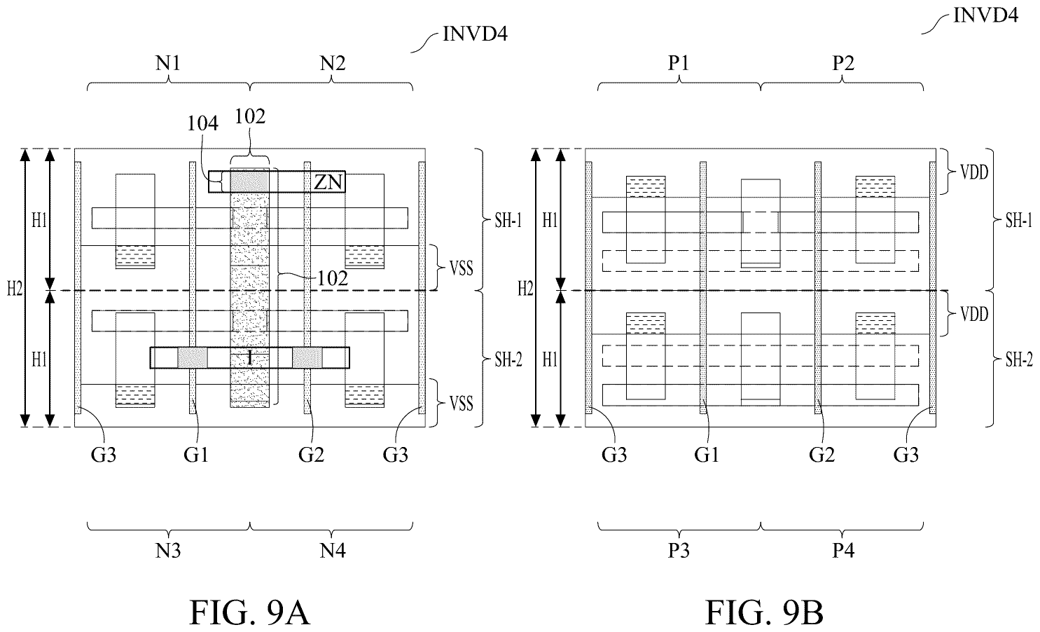

FIGS. 9A and 9B illustrate the layout of a front side and a backside, respectively of an inverter INVD4 in accordance with some embodiments. Throughout the description, a layout may include an upper part and a lower part, for example, separated by a delineation line, which may be the middle level of the dielectric isolation layers 56 as shown in FIG. 7. The term “front side” of a layout refers to the part of the structure over the delineation line, and may include upper transistors (such as transistors 10U in FIG. 7), the respective front metal lines on the front side of the transistor, and the parts of the vertical interconnection over the delineation line.

The term “backside” of a layout refers to the part of the structure lower than the delineation line, and may include lower transistors (such as transistors 10L in FIG. 7), the respective backside metal lines on the backside of the transistor, and the parts of the vertical interconnection lower than the delineation line.

FIG. 9A illustrates the front side of the inverter INVD4 in accordance with some embodiment. The cell height of inverter INVD4 is double height H2, which is two times the single height H1. In accordance with some embodiments, the single height H1 is the unit cell height for designing integrated circuits. The corresponding cell library and the integrated circuits that are laid out and manufactured on wafers may also have the single height H1. When viewed in the top view, a single-height cell has a VDD line extending to a first edge of the single-height cell, and a VSS line extending to a second edge (of the single-height cell) parallel to and opposite to the first edge.

The VDD line and the VSS line may be on the opposite sides (front side and backside) of the transistors and the corresponding device die. Correspondingly, a double-height standard cell includes two VSS lines and two VDD lines separated into two single-height parts, with each of the two single-height parts having a single height H1, and includes a VDD line and a VSS line. Throughout the description, the illustrated single-height parts include a first single-height part SH-1 (when viewed in the layout, which is also in top view) and a second single-height part SH-2.

Referring to FIG. 9A again, inverter INVD4 includes two VSS lines VSS, each extending to the bottom edge of the illustrated single-height parts SH-1 and SH-2. The horizontal metal lines in FIG. 9A are in bottom metal layer M0. The gate stacks G1 and G2 are under the bottom metal layer M0. The first single-height part SH-1 is abutted to the second single-height part SH-2. The front side of the first single-height part SH-1 includes NMOS transistors N1 and N2. The front side of the second single-height part SH-2 includes NMOS transistors N3 and N4.

As shown in FIG. 9B, the backside of the first single-height part SH-1 includes PMOS transistors P1 and P2. The backside of the first single-height part SH-2 includes PMOS transistors P3 and P4. Common gates G1 and G2 (which may be the gate stacks 90 in FIG. 7) extend into both of the single-height parts SH-1 and SH-2, and extend from the front side to the backside, as shown in FIGS. 9A and 9B. At the boundaries of the standard cell INVD4, there are dummy gate stacks G3.

As shown in FIG. 9A, drain contact plug 102 continuously extend into single-height parts SH-1 and SH-2. The drain contact plug 102 electrically interconnects the drain regions of NMOS transistors N1, N2, N3, and N4 and PMOS transistors P1, P2, P3, and P4. While not shown in FIG. 7, the drain contact plug 102 will penetrate through ILDs 72 and 68, and are electrically connected to the source/drain regions 62L and 62U of the NMOS transistors N1, N2, N3, and N4 and PMOS transistors P1, P2, P3, and P4. Conductive feature 104 may be a vertical interconnect that is used to connect the drain regions of the PMOS transistors P1, P2, P3, and P4 to output metal line ZN. Alternatively, when drain contact plug 102 already interconnects the drain regions of all eight transistors, conductive feature 104 may be a via connecting the drain contact plug 102 to the output metal line ZN. Output metal line ZN may partially overlap VDD line in single-height part SH-1.

In accordance with some embodiments, each of the single-height parts SH-1 and SH-2 is able to accommodate two metal lines parallel to the VSS line and in the bottom (front-side) metal layer Mo. As shown in FIG. 9A, one metal line in single-height part SH-1 is used as the output metal line ZN, and one metal line in in single-height part SH-2 is used as the input metal line I. Accordingly, by adopting a double-height structure, the output metal line ZN and the input metal line I are spaced far apart from each other. The parasitic capacitance is reduced, and the performance of the inverter INVD4 is improved.

As a comparison, if the inverter INVD4 is designed as a single-height standard cell, the two metal lines that can be accommodated in the single-height structure has to be used for the input metal line I and output metal ZN, which are close to each other. The parasitic capacitance is thus high, and the performance is degraded.

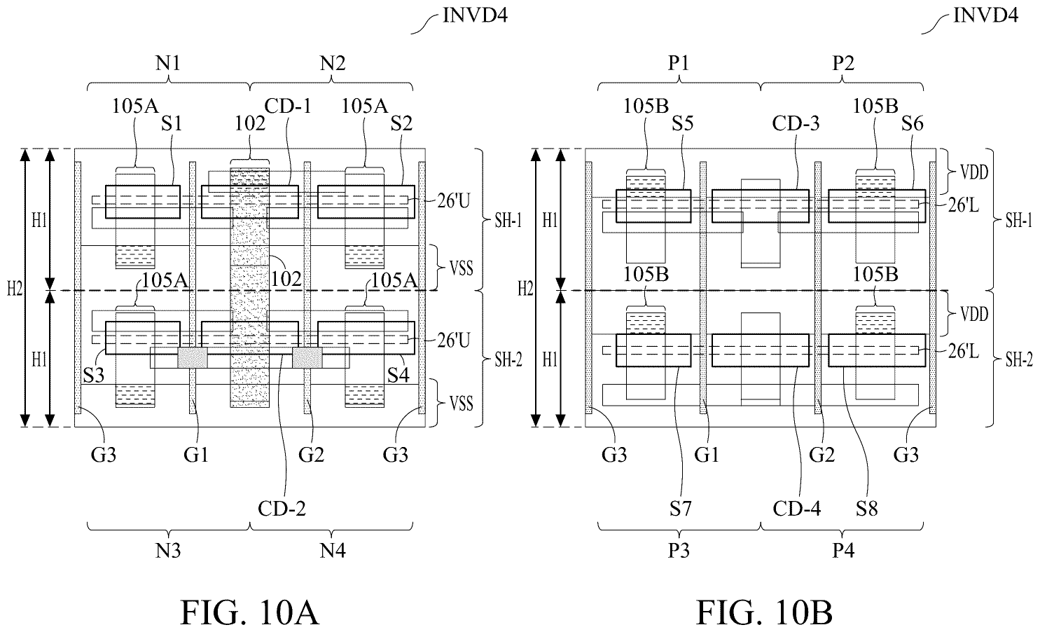

FIG. 10A illustrates the front-side layout of inverter INVD4. FIGS. 9A and 10A illustrate the same front side structures of the inverter INVD4, except that some conductive features are illustrated in FIG. 9A, while the semiconductor nanostructures and source/drain regions are shown in FIG. 10A, so that the features may be illustrated clearer.

FIG. 10A illustrates semiconductor nanostructures 26′U (also refer to FIG. 7) as the channels. The source regions S-1 and S-2 are the source regions of NMOS transistors N1 and N2, respectively. A common drain CD-1 is between two gate stacks G1 and G2, and is connected to drain contact plug 102 (FIG. 9A), which is further connected to output metal line ZN. It is appreciated that although common drain CD-1 is illustrated as being one piece, it may also be separated into two pieces that are on the opposing sides of the drain contact plug 102.

Similarly, FIG. 10A also illustrates the source regions S-3 and S-4, which are the source regions of NMOS transistors N3 and N4, respectively. A common drain CD-2 is between two gate stacks G1 and G2, and is connected to drain contact plug 102 (FIG. 9A), which is further connected to output metal line ZN. It is appreciated that although common drain CD-2 is illustrated as being one piece, it may also be separated into two pieces that are on the opposing sides of the drain contact plug 102. Conductive features 105A (FIG. 10A) connect the source regions of NMOS transistors N1, N2, N3, and N4 to the VSS lines, and conductive features 105B (FIG. 10B) connect the source regions of PMOS transistors P1, P2, P3, and P4 to the VDD lines.

FIGS. 9B and 10B illustrate the same front side structures of the inverter INVD4, except that some backside metal lines are illustrated as being dashed in FIG. 9B, while the semiconductor nanostructures and source/drain regions are shown in FIG. 10B, so that the features may be seen clearer.

FIG. 9B illustrate the metal lines on the backside of the transistor and parallel to the VDD lines. FIG. 10B illustrates semiconductor nanostructures 26′L (also refer to FIG. 7) as the channels, and the source regions S-5 and S-6, which are the source regions of PMOS transistors P1 and P2, respectively. A common drain CD-3 is between two gate stacks G1 and G2, and is connected to drain contact plug 102 (FIG. 9A), which is further connected to output metal line ZN. The common drain CD-3 may also be formed as two separate pieces.

Similarly, FIG. 10B also illustrates the source regions S-7 and S-8, which are the source regions of PMOS transistors P3 and P4, respectively. A common drain CD-4 is between two gate stacks G1 and G2, and is connected to conductive feature 102 (when it is a vertical interconnect in FIG. 9A), which is further connected to output metal line ZN. The common drain CD-4 may also be formed as two separate pieces.

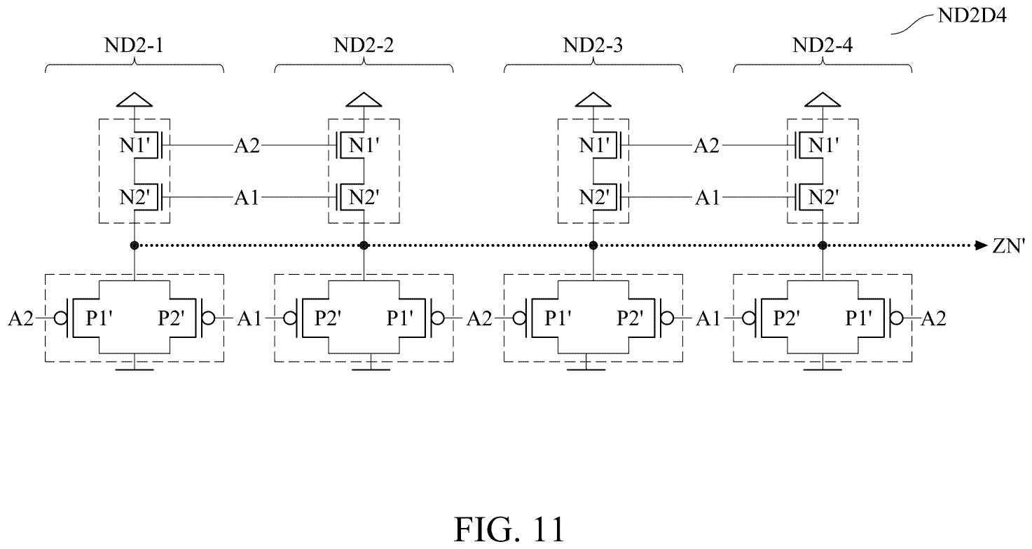

FIG. 11 illustrates a circuit schematic of a NAND cell (ND2D4), which includes four ND2 cells ND2-1, ND2-2, ND2-3, and ND2-4 connected in parallel. Each of the ND2 cells ND2-1, ND2-2, ND2-3, and ND2-4 includes a first input A1, with all inputs A1 being interconnected. Each of the ND2 cells ND2-1, ND2-2, ND2-3, and ND2-4 further includes a second input A2, with all inputs A2 being interconnected. The outputs of the ND2 cells are interconnected to form output ZN′.

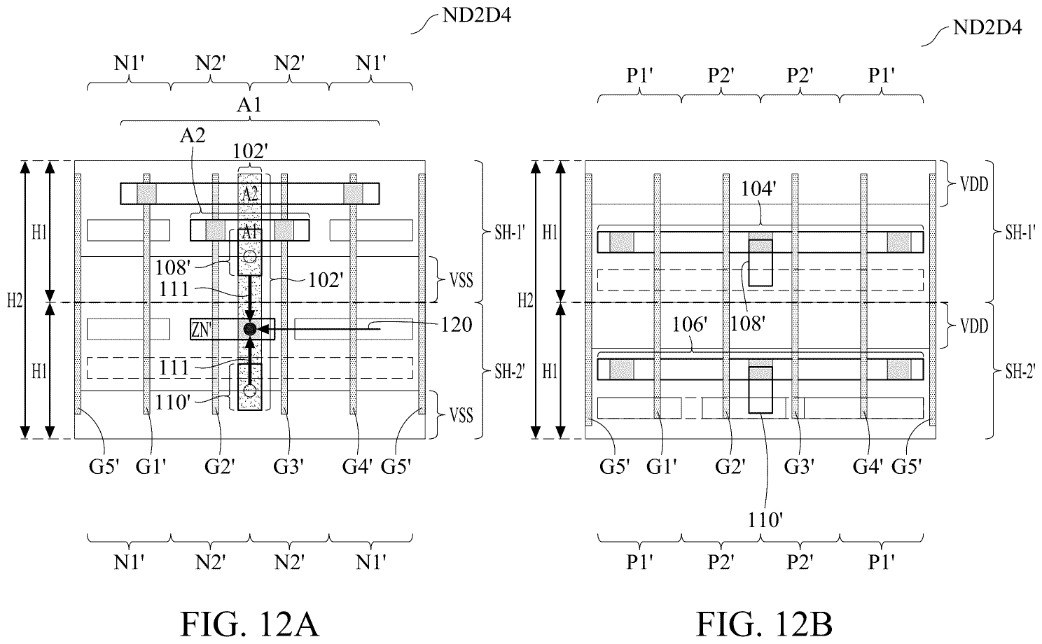

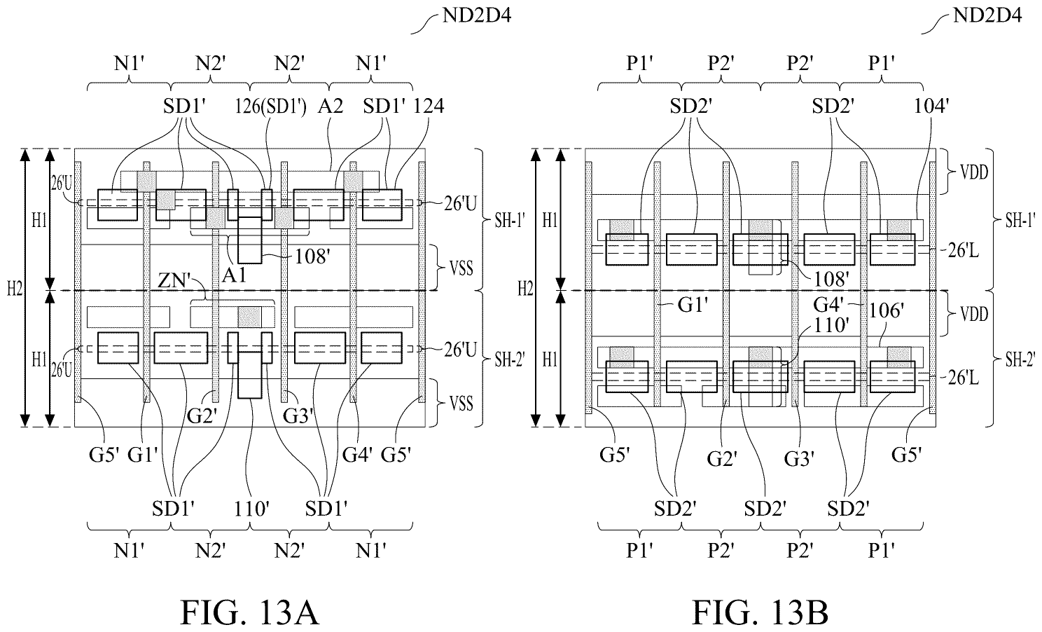

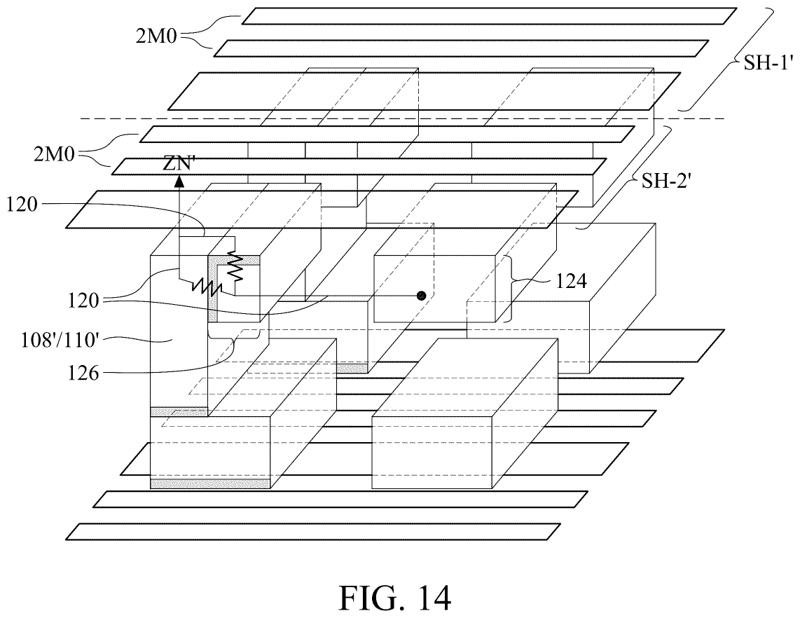

FIGS. 12A and 13A illustrate the front sides (NMOS transistors) of the NAND cell ND2D4 in accordance with some embodiments, wherein some features are separated into FIGS. 12A and 13A for clear views. The horizontal metal lines in FIG. 12A are in bottom metal layer Mo. The gate stacks G1′, G2′, G3′, and G4′ are under the bottom metal layer Mo. The NAND cell ND2D4 also has a double-height structure that includes two single-height parts SH-1′ and SH-2′, each having height H1, so that the total height H2 is equal to 2×H1. Each of gate stacks G1′, G2′, G3′, and G4′ extends into both of single-height parts SH-1′ and SH-2′. Furthermore, each of gate stacks G1′, G2′, G3′, and G4′ extend into the front side structures as shown in FIGS. 13A and 14A, and into the backside structures as shown in FIGS. 13B and 14B. At the boundaries of the NAND cell ND2D4, there are dummy gate stacks G5′.

FIG. 13A illustrates semiconductor nanostructures 26′U (also refer to FIG. 7) as the channels, and source/drain regions. In each of the first single-height part SH-1′ and SH-2′, each of the gate stacks G1′, G2′, G3′, and G4′ forms an NMOS transistors N1′ or N2′ with the corresponding source/drain regions SD1′ that are on the opposite sides of the respective gate stacks G1′, G2′, G3′, and G4′. Accordingly, four NMOS transistors N1′ and four NMOS transistors N2′ are formed, and are split evenly into the single-height parts SH-1′ and SH-2′.

FIG. 12A illustrates the input metal lines A1 and A2 in metal layer Mo, which is the lowest metal layer on the front side of the transistors. In accordance with some embodiments, both of input metal lines A1 and A2 are formed in the single-height part SH-1′. The output metal line ZN′, on the other hand, is formed in the single-height part SH-2′. Source/drain contact plug 102′, which extends into both of the single-height parts SH-1′ and SH-2′, is used to electrically connect the common source/drain regions of transistors N1′ and P1′ to the output metal line ZN′. Source/drain contact plug 102′ further electrically connects the common source/drain regions of transistors N2′ and P2′ (FIG. 11) to the output metal line ZN′.

FIGS. 12B and 13B illustrate the backsides (PMOS transistors) of the NAND cell ND2D4 in accordance with some embodiments, wherein some features are separated into FIGS. 12B and 13B for clear views. As shown in FIG. 12B, backside metal line 104′ and 106′ are formed in single-height parts SH-1′ and SH-2′ respectively.

FIG. 13B illustrates semiconductor nanostructures 26′L (also refer to FIG. 7) as the channels, and source/drain regions SD2′. In each of the single-height parts SH-1′ and SH-2′, each of the gate stacks G1′, G2′, G3′, and G4′ forms a PMOS P1′ or P2′ with the corresponding source/drain regions SD2′ that are on the opposite sides of the respective gate stacks G1′, G2′, G3′, and G4′. Accordingly, four PMOS transistors P1′ and four PMOS transistors P2′ are formed and are split evenly into the single-height parts SH-1′ and SH-2′.

FIG. 12B illustrates metal line 104′ in single-height part SH-1′. Metal line 104′ is on the backside of the transistors, and may be in the same metal layer as that of VDD lines, which are under the PMOS transistors P1′ and P2′. Metal line 104′ electrically interconnects the drain regions of four PMOS transistors P1′ and P2′ (refer to FIG. 13B), and is connected to vertical interconnect 108′. The vertical interconnect 108′ is used to connect the backside features to the front side, as is also shown in FIG. 13B. The vertical interconnect 108′ may be connected to the front-side source/drain contact plug 102′ (FIG. 12A), which is further connected to the output metal line ZN′. The connection paths are represented by the arrows 111 as shown in FIG. 12A.

FIG. 12B also illustrates metal line 106′ in single-height part SH-2′. Metal line 106′ is on the backside of the transistors, and may be in the same metal layer as that of VDD lines. Metal line 106′ electrically interconnects the drain regions of four PMOS transistors P1′ and P2′ (refer to FIG. 13B), and is connected to vertical interconnect 110′. The vertical interconnect 110′ is used to connect the backside features to the front side, as is also shown in FIG. 13B. The vertical interconnect 110′ may be connected to the front-side source/drain contact plug 102′ (FIG. 12A), which is further connected to the output metal line ZN′, as represented by the arrows 111 as shown in FIG. 12A.

FIG. 14 illustrates a schematic perspective view of a part of the NAND cell ND2D4 in accordance with some embodiments, wherein the illustrated part includes the right parts of the NAND cell ND2D4, which right part includes the front side as shown in FIG. 12A and the backside as shown in FIG. 12B. The rightmost drain region 124 and the source region 126 (also refer to FIG. 13A) are illustrated, while the source/drain region and the gate in between are not shown. The two metal lines (2M0) in metal layer M0 are schematically illustrated, and no more metal line can be accommodated in a single-height part.

The signal path 120 pointing from drain region 124 to the source region 126, and then to output metal line ZN′ are illustrated. The signal path 120 connects the rightmost drain region 124 and the source/drain regions and channels on its left to output metal line ZN′. It is observed that the entire signal path 120 is on the front side of the cell, and does not go to the backside of the transistors. Accordingly, the signal path is short, and the number of components in the signal paths 120 is not significant. The resistance of the signal paths 120 is thus low, and the performance of the NAND cell ND2D4 is high. This advantageous feature is resulted due to the use of double-height design, which allows room for the output metal line ZN′ to be placed in a different single-height part than at least one or both of the input metal lines A1 and A2.

As a comparison, if NAND cell ND2D4 is designed as a single-height cell, all of the eight PMOS transistors have to be placed into one row, and all of the eight NMOS transistors have to be placed into one row. The length of the row is thus long. Since input metal lines A1 and A2 already use up the two allowed metal lines, the output metal line ZN′ has to be placed at one end of the long row. Signal may need to be routed to one end of the long row, go to the backside of the die, and conducted to the opposite end and to the output metal line ZN′. The long signal lines and the increased number of components results in the increase in the resistance of the signal path, and the degradation of the performance of the cells.

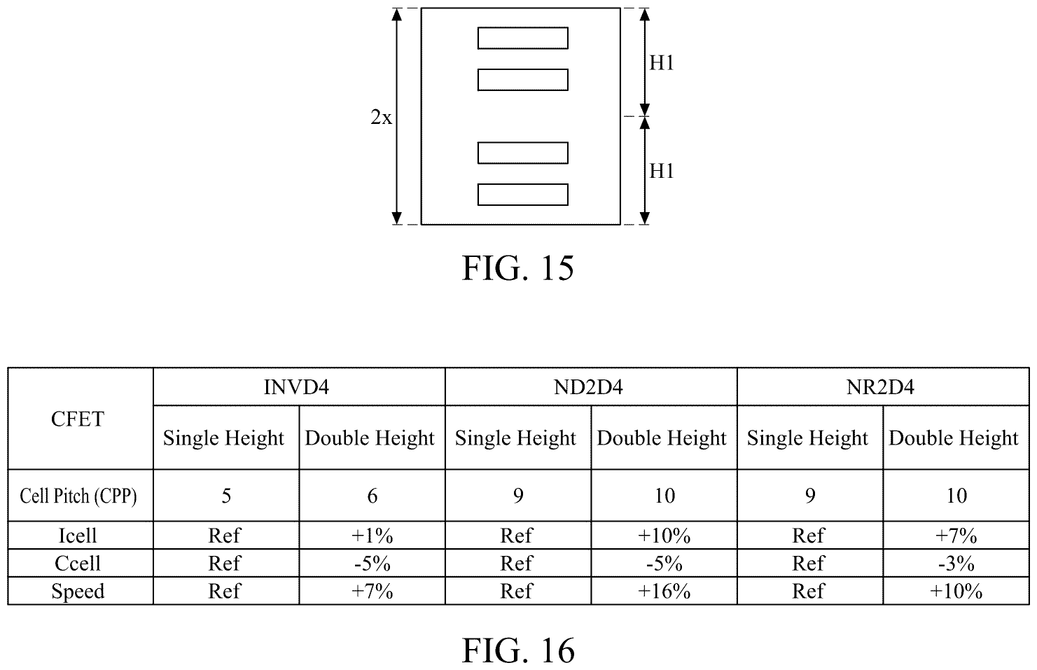

FIG. 15 schematically illustrates a block view of a standard cell having a double height design, wherein four metal lines are allowed in the double-height standard cell (and in the bottom metal layer M0). This increases the flexibility in the routing.

FIG. 16 illustrates a table showing some inverters INVD4, NAND cells ND2D4, and NOR gates NR2D4 (each having four NOR gates connected in parallel) in accordance with some embodiments. Single-height design of these standard cells are used as references, and the cell current Icell, capacitance Ccell, and speed of the double-height design are compared to that of the single-height design. The table shown in FIG. 16 illustrates that each of the double-height design uses one more cell pitch (CPP, also refer to as gate pitch, which is the distance between neighboring gate stacks) than the respective single-height design. Such penalty in the chip area results in improved cell currents ICell, reduced capacitance Ccell, and improved speed. For example, the speed of the NAND cell ND2D4 may be improved by 16 percent over that of the single-height design.

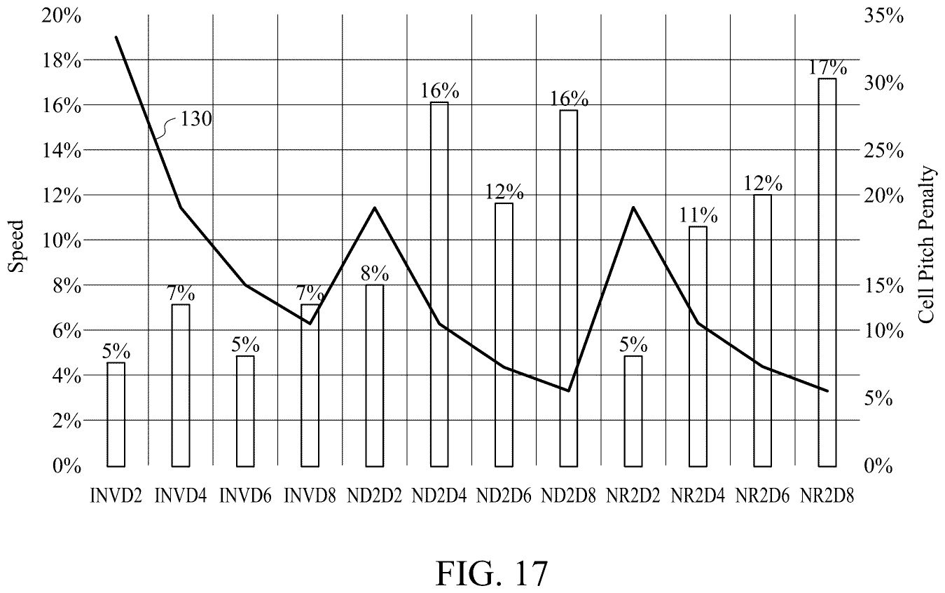

FIG. 17 illustrates the speed improvement of the standard cells and the cell pitch penalty of some standard cells in accordance with some embodiments. The X-axis illustrates some example types of standard cells. The left Y-axis represents the speed improvement of the double-height cells over the respective single-height cells, and corresponds to the illustrated vertical bars. It shows, for example, that the inverters INVD2, INVDD4, INVD6, and INVD8, which have two, four, six, and eight inverters, respectively, connected in parallel, the speed improvement is 5%, 7%, 5%, and 7%, respectively. The speed improvement of the NAND cells ND2D2, ND2D4, ND2D6, and ND2D8 are 6%, 16%, 12%, and 16%, respectively. The last digit of these cells represents how many of the same type of cells connected in parallel. The speed improvement of the NOR gates NR2D2, NR2D4, NR2D6, and NR2D8 are 5%, 11%, 12%, and 17%, respectively.

The line 130 illustrates the cell pitch area penalty of the corresponding standard cells in percentages, which are shown by the right Y-axis. Line 130 also illustrates the increase in the percentage calculated based on the needed number of CPP in the respective single-height design.

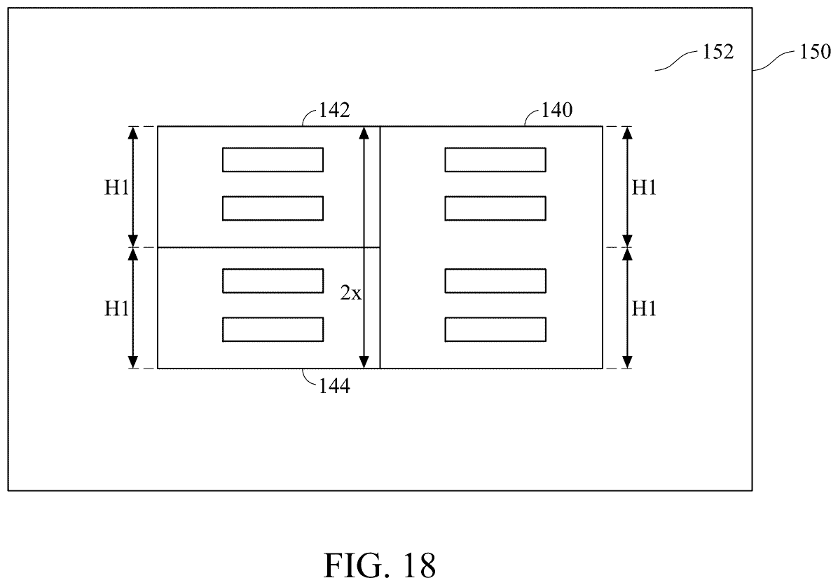

The double-height cells as discussed throughout the description are saved in cell library, and are also formed on physical wafers/dies. Furthermore, in a device die, there may exist both single-height standard cells and double height standard cells. For example, FIG. 18 illustrates a device die 150 (which may be formed on a silicon substrate), which includes circuit 152. The circuit 152 includes double-height standard cell 140 and two single-height cells 142 and 144, which may be abutting and in a same row as the double-height standard cell 140. The single-height cells 142 and 144 collectively occupy two rows, while double-height standard cell 140 alone occupies two rows. The single-height cells 142 and 144 may be inverters (INV), INVD2, ND2D2, NR2, NR2D2, or the like, which have fewer identical cells connected in parallel. The double-height cell 140 may be INVD4, INVD6, INVD8, ND2D4, ND2D6, ND2D8, NR2D4, NR2D6, NR2D8, or the like, which have more identical cells connected in parallel.

The embodiments of the present disclosure have some advantageous features. By forming double-height cells for some standard cells that have multiple identical devices/circuits connected in parallel, the parasitic capacitance between the input and the output of double-height cells may be reduced, and device performance may be improved.

In accordance with some embodiments of the present disclosure, a structure comprises a standard cell comprising a first single-height part comprising a first VDD line; and a first VSS line; a first input metal line; and a second single-height part abutting the first single-height part to form an interface, wherein the second single-height part comprises a second VDD line; a second VSS line; and an output metal line, wherein in a top view of the structure, the first input metal line and the output metal line have lengthwise directions parallel to the interface. In an embodiment, the standard cell comprises a first transistor of a first conductivity type; and a second transistor of a second conductivity type opposite to the first conductivity type, wherein the second transistor overlaps the first transistor, and wherein a first one of the first VSS line and the first VDD line is higher than the second transistor.

In an embodiment, a second one of the first VSS line and the first VDD line is lower than the first transistor. In an embodiment, the structure further comprises a vertical interconnect connecting the first transistor to the output metal line. In an embodiment, the standard cell comprises four inverters connected in parallel. In an embodiment, the structure further comprises a drain contact plug continuously extending into both of the first single-height part and the second single-height part, wherein the drain contact plug electrically connects common drain regions of transistors in the four inverters to the output metal line.

In an embodiment, in the top view of the structure, the drain contact plug has a lengthwise direction perpendicular to the interface. In an embodiment, in the top view of the structure, the drain contact plug is in middle of the standard cell. In an embodiment, wherein the standard cell occupies three gate pitches, and wherein a gate pitch is a distance between two neighboring gate stacks of transistors in the standard cell. In an embodiment, the standard cell comprises four NAND cells connected in parallel.

In an embodiment, the structure further comprises a second input metal line in the first single-height part and parallel to the first input metal line. In an embodiment, the structure further comprises a source/drain contact plug continuously extending into both of the first single-height part and the second single-height part, wherein the source/drain contact plug connects common drain regions of transistors in the four NAND cells to the output metal line. In an embodiment, in the top view of the structure, the source/drain contact plug has a lengthwise direction perpendicular to the interface.

In an embodiment, the standard cell comprises a first transistor and a second transistor of a first conductivity type; and a third transistor and a fourth transistor of a second conductivity type opposite to the first conductivity type, wherein the third transistor and the fourth transistor overlap the first transistor and the second transistor respectively, and wherein the structure further comprises a first vertical interconnect connecting the first transistor to the output metal line, wherein the first vertical interconnect is in the first single-height part; and a second vertical interconnect connecting the second transistor to the output metal line, wherein the second vertical interconnect is in the second single-height part. In an embodiment, the standard cell occupies five gate pitches, and wherein a gate pitch is a distance between two neighboring gate stacks of transistor in the standard cell.

In accordance with some embodiments of the present disclosure, a structure comprises an inverter cell comprising a first single-height part comprising a first VSS line at a first edge of the first single-height part; and an input metal line; and a second single-height part comprising a first VDD line at a first edge of the second single-height part, wherein the first edge of the first single-height part abuts the first edge of the second single-height part; and an output metal line, wherein in a top view of the inverter cell, the input metal line is spaced apart from the output metal line by the first VSS line.

In an embodiment, in the top view, the input metal line is further spaced apart from the output metal line by the first VDD line. In an embodiment, in a cross-sectional view of the structure, the first VSS line and the first VDD line are on opposite sides of transistors of the inverter cell.

In accordance with some embodiments of the present disclosure, a structure comprises an inverter cell comprising four inverters, wherein the inverter cell comprises a first edge and a second edge parallel to each other; a first VDD line extending to the first edge; a first VSS line extending to the second edge; a second VDD line extending to a middle line of the inverter cell, wherein the middle line is in a middle between the first edge and the second edge; an input metal line electrically coupled to inputs of the four inverters, wherein in a top view of the inverter cell, the input metal line is parallel to, and is between, the second VDD line and the first VSS line; and an output metal line electrically coupled to outputs of the four inverters, wherein in the top view of the inverter cell, the output metal line is parallel to, and partially overlaps the first VDD line.

In an embodiment, the structure further comprises a contact plug having a first lengthwise direction perpendicular to a second lengthwise direction of the first VDD line, wherein the contact plug is at a level lower than the first VSS line and higher than the first VDD line, and wherein a first end of the contact plug overlaps a first portion of the first VDD line, and a second end of the contact plug is overlapped by a second portion of the first VSS line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a standard cell comprising:
a first single-height part comprising:
a first VDD line;
a first VSS line; and
a first input metal line;
a second single-height part abutting the first single-height part to form an interface, wherein the second single-height part comprises:
a second VDD line;
a second VSS line; and
an output metal line, wherein in a top view of the structure, the first input metal line and the output metal line have lengthwise directions parallel to the interface wherein the standard cell comprises:
a first transistor of a first conductivity type; and
a second transistor of a second conductivity type opposite to the first conductivity type, wherein the second transistor overlaps the first transistor, wherein a first one of the first VSS line and the first VDD line is higher than the second transistor, and wherein the standard cell comprises four inverters connected in parallel.
